(19) United States
(12) Patent Application Publication
(10) Pub. No.: US 2010/0286423 A1
(43) Pub. Date: Nov. 11, 2010

(54) NICKEL-CONTAINING FILM-FORMING MATERIAL AND PROCESS FOR PRODUCING NICKEL-CONTAINING FILM

(75) Inventors: Toshitaka Hiro, Tokyo (JP); Takamitsu Kobayashi, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Showa Denko K.K., Minato-ku, Tokyo (JP)

(21) Appl. No.: 12/810,257

(22) PCT Filed: Dec. 16, 2008
(86) PCT No.: PCT/JP2008/072890

§ 371 Date: Jun. 23, 2010

(30) Foreign Application Priority Data
Dec. 25, 2007 (JP) 2007-332387

(51) Int. Cl. C07F 17/00; C23C 16/00

(52) U.S. Cl. 556/11; 427/255.28

(57) ABSTRACT

A nickel-containing film-forming material including a compound represented by a structure of the following formula (1). In the formula (1), R¹ and R² are each independently a hydrogen atom or a group represented by a structure of the following formula (2), a and b are each an integer of 0 to 4, and a and b satisfy the condition of 0<a+b≦4 with the exception of a case where R¹ and R² are both hydrogen atoms. In the formula (2), R³, R⁴ and R⁵ are each independently an alkyl group of 1 to 2 carbon atoms.

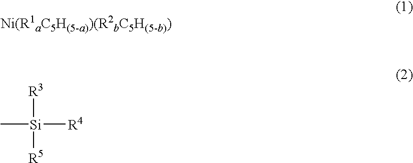

### TECHNICAL FIELD

The present invention relates to a material for forming a nickel-containing film by a CVD (chemical vapor deposition) method, preferably a nickel-containing film-forming material for forming a nickel silicide film by a CVD method, and a process for producing a nickel silicide film using the material.

### BACKGROUND ART

Advancement of technology in semiconductor devices is remarkable at present. In order to make operations of a higher speed possible, further advancement and fining have been rapidly carried out, and material development for them has been actively carried out.

In wiring materials, low-resistance materials have been introduced one after another, and by forming a silicide film on a gate electrode or a source or drain diffusion layer, further lowering of resistance has been made. It has been studied to introduce nickel silicide having lower resistance than titanium silicide or cobalt silicide into the silicide film used herein.

Formation of the nickel silicide has been carried out by a sputtering method so far. In the sputtering method, however, there is a fear of physical damage to a semiconductor device, and besides, it is difficult to uniformly produce a film. For such reasons, formation of nickel silicide by a CVD method has been studied recently.

The CVD method is a method wherein a film-forming material is volatilized and made to flow in a gas state, and utilizing chemical reaction a film is formed on a silicon substrate in a reaction container. By carrying out the CVD method under reduced pressure, film production can be carried out at a low temperature, but the conditions in the film production greatly vary depending upon differences of the film-forming material used. Properties required for the film-forming material used herein are as follows: the material has a high vapor pressure, the material is a liquid from the viewpoint of handling, etc.

Of nickel film-forming materials having been heretofore proposed, bis(alkylcyclopentadienyl)nickel wherein an alkyl group has been introduced into cabaltocene (patent document 1), cyclopentadienylallyl nickel (patent document 2) and tetrakis(trifluorophosphine)nickel (patent document 3) have been reported as compounds which can be handled as a liquid.

In bis(alkylcyclopentadienyl)nickel, cyclopentadienylallyl nickel or the like, cyclopentadiene that is a ligand is liable to be dimerized, so that care must be taken in handling in its production process, and if it is dimerized, thermal decomposition needs to be carried out. Thus, there are problems in synthesis and storing in the industrial production. For tetrakis(trifluorophosphine)nickel, bis(alkylcyclopentadienyl)nickel is used as a raw material for synthesis, so that it can be said that there is the same problem as in the above compounds.

On that account, in order to more readily carry out formation of a nickel-containing film by a CVD method, development of a material which has a low melting point, can be utilized as a liquid, has a high vapor pressure, can be readily synthesized industrially and is stable has been desired.

Patent document 1: Japanese Patent Laid-Open Publication No. 328130/2003

Patent document 2: Japanese Patent Laid-Open Publication No. 93732/2005

Patent document 3: Japanese Patent Laid-Open Publication No. 45649/2006

### DISCLOSURE OF THE INVENTION

### Problem to be Solved by the Invention

The present invention is intended to solve such problems associated with prior art as described above, and it is an object of the invention to provide a nickel-containing film-forming material which has a low melting point, can be handled as a liquid, has a high vapor pressure, can be readily synthesized industrially, is stable and is suitable for formation of a nickel-containing film by a CVD method, preferably formation of a nickel silicide film by a CVD method.

It is another object of the invention to provide a process for producing a nickel silicide film using the above-mentioned nickel-containing film-forming material.

### Means to Solve the Problem

As a result of studies of the above problems, it has been found that a nickel-containing film-forming material represented by a structure of the following formula (1) is a film-forming material which has a low melting point, can be utilized as a liquid, has a high vapor pressure, can be readily synthesized industrially, is stable and is suitable for formation of a nickel-containing film by a CVD method, preferably formation of a nickel silicide film.

That is to say, the present invention relates to the following 1 to 9.

1. A nickel-containing film-forming material comprising a compound represented by a structure formula of the following formula (1):

Ni(R¹ₐC₅H₍₅₋ₐ₎)(R²_{b}C₅H_{(5-b)}) (1)

wherein C₅H₍₅₋ₐ₎ and C₅H_{(5-b)} are each a cyclopentadienyl ring, R¹ and R² are each independently a hydrogen atom or a group represented by a structural formula of the following formula (2), and a and b are integers satisfying the condition of 0<a+b≦4 with the exception of a case where R¹ and R² are both hydrogen atoms,

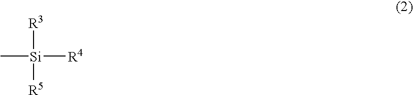

wherein R³, R⁴ and R⁵ are each independently an alkyl group of 1 to 2 carbon atoms.

2. The nickel-containing film-forming material as stated in 1, wherein R³, R⁴ and R⁵ in the formula (2) are all methyl groups.

3. The nickel-containing film-forming material as stated in 1, wherein the compound represented by a structural formula of the formula (1) is bis(trimethylsilylcyclopentadienyl)nickel or (cyclopentadienyl)(trimethylsilylcyclopentadienyl)nickel.

4. The nickel-containing film-forming material as stated in any one of 1 to 3, which is a material for forming a nickel-containing film using a CVD (chemical vapor deposition) method.

5. The nickel-containing film-forming material as stated in 4, wherein the nickel-containing film is a nickel silicide film.

6. A nickel silicide film formed by the use of the nickel-containing film-forming material as stated in any one of 1 to 5.

7. A process for producing a nickel silicide film, comprising forming a nickel silicide film by a CVD (chemical vapor deposition) method using the nickel-containing film-forming material as stated in any one of 1 to 5.

8. The process for producing a nickel silicide film as stated in 7, wherein as a silicon source of the nickel silicide film, silicon in the group represented by a structure of the formula (2) is utilized.

9. The process for producing a nickel silicide film as stated in 7 or 8, wherein the nickel-containing film-forming material is bis(trimethylsilylcyclopentadienyl)nickel or (cyclopentadienyl)(trimethylsilylcyclopentadienyl)nickel.

### EFFECT OF THE INVENTION

According to the present invention, a nickel-containing film-forming material which has a low melting point, can be utilized as a liquid, has a high vapor pressure, can be readily synthesized industrially, is stable and is suitable for formation of a nickel-containing film by a CVD method, preferably formation of a nickel silicide film by a CVD method, is provided.

That is to say, by the use of this nickel-containing film-forming material, a nickel-containing film, preferably a nickel silicide film, can be readily formed by a CVD method.

### BRIEF DESCRIPTION OF THE DRAWING

FIG. 1 is a schematic view of a CVD apparatus.

### BEST MODE FOR CARRYING OUT THE INVENTION

The nickel-containing film-forming material of the invention is described in detail hereinafter.

The nickel-containing film-forming material of the invention comprises a compound having a structural formula represented by the aforesaid formula (1) (sometimes referred to as a “nickel compound” simply hereinafter).

In the formula (1), C₅H₍₅₋ₐ₎ and C₅H_{(5-b)} are each a cyclopentadienyl ring. R¹ and R² are each independently a hydrogen atom or a group having a structural formula represented by the aforesaid formula (2). a and b are each an integer of 0 to 4, and a and b satisfy the condition of 0<a+b≦4 with the exception of a case where R¹ and R² are both hydrogen atoms.

Synthesis of the compound satisfying the condition of a=b=1, namely a+b=2, with the exception of a case where R¹ and R² are both hydrogen atoms can be carried out most readily. Synthesis of the compound satisfying the condition of a+b=1 is highly difficult, but this compound is superior in properties required for forming a nickel-containing film by a CVD method. On that account, when a and b satisfy the condition of 0<a+b≦2 with the exception of a case where R¹ and R² are both hydrogen atoms, a more preferred nickel-containing film-forming material can be obtained.

R³, R⁴ and R⁵ in the formula (2) are each independently a hydrogen atom or an alkyl group of 1 to 2 carbon atoms. As the alkyl group of 1 to 2 carbon atoms, a methyl group or an ethyl group can be mentioned. R³, R⁴ and R⁵ are each preferably a methyl group because synthesis of a nickel-containing film-forming material is easy and the molecular weight becomes lowest. Therefore, it is preferable that all of R³, R⁴ and R⁵ are methyl groups.

Examples of the nickel compounds used for the nickel-containing film-forming material of the invention include (cyclopentadienyl)(trimethylsilylcyclopentadienyl)nickel (following formula (I)), (cyclopentadienyl)(ethyldimethylsilylcyclopentadienyl)nickel (following formula (II)), (cyclopentadienyl)(diethylmethylsilylcyclopentadienyl)nickel (following formula (III)), (cyclopentadienyl)(triethylsilylcyclopentadienyl)nickel (following formula (IV)), bis(trimethylsilylcyclopentadienyl)nickel (following formula (V)), bis(ethyldimethylsilylcyclopentadienyl)nickel (following formula (VI)), bis(diethylmethylsilylcyclopentadienyl)nickel (following formula (VII)), bis(triethylsilylcyclopentadienyl)nickel (following formula (VIII)), and (cyclopentadienyl)(1,3-bis(trimethylsilyl)cyclopentadienyl)nickel (following formula (IX)).

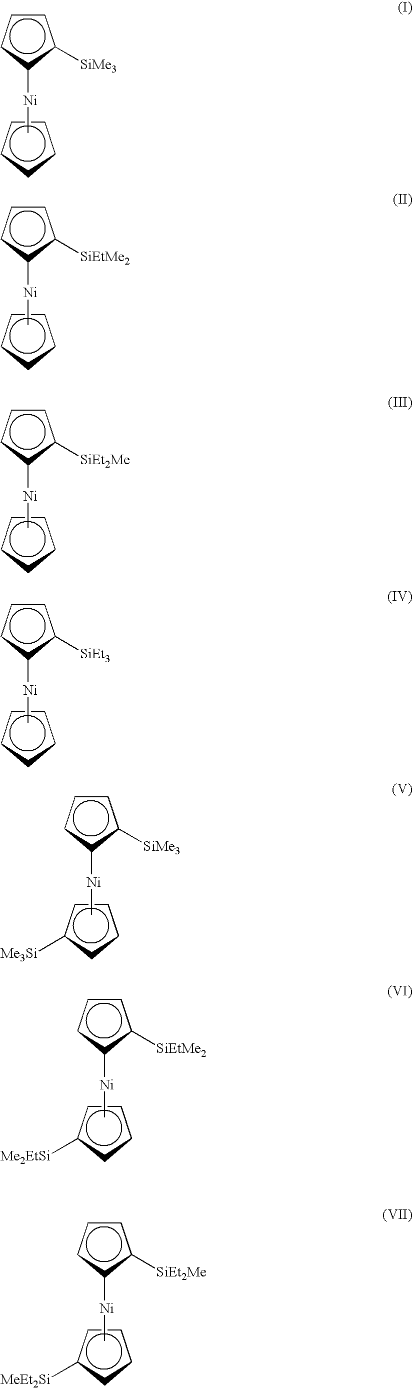

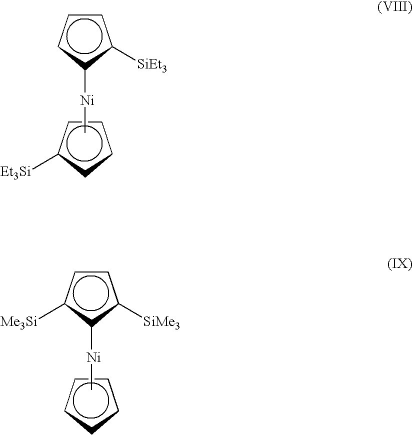

Of these nickel compounds, bis(trimethylsilylcyclopentadienyl)nickel is particularly preferable as a compound used for a film-forming material that is suitable for forming a nickel-containing film, particularly a nickel silicide film, by a CVD method because it has a high vapor pressure, can be readily synthesized industrially and is stable.

Moreover, bis(trimethylsilylcyclopentadienyl)nickel is hardly dimerized. This is considered to be attributable to steric hindrance. On this account, bis(trimethylsilylcyclopentadienyl)nickel can be readily handled in its production process, and the burden of synthesis and storage in the industrial production is small.

In order to form a nickel-containing film, particularly a nickel silicide film, by the use a CVD method, the compound used for the nickel-containing film-forming material of the invention preferably satisfies the requirements: (1) the melting point is low, (2) the temperature at which the vapor pressure becomes 1 Torr is low, and (3) the compound is stable. That is to say, (1) the melting point is preferably not higher than the environmental temperature in the initial stage of the film production process, and is more preferably, for example, not higher than 50° C., (2) the temperature at which the vapor pressure becomes 1 Torr is preferably not higher than 150° C. in the industrial production, and (3) the volatilization ratio given when the compound is heated up to 500° C. is preferably not lower than 99.5%. When a nickel compound satisfying these requirements is used, a preferred nickel-containing film-forming material is obtained.

The nickel-containing film-forming material of the invention may be composed of only the nickel compound, or can contain, in addition to the nickel compound, other substances as long as the objects of the invention can be attained. For example, in the case where a metal silicide film is produced by a CVD method using the nickel-containing film-forming material of the invention as described later, the nickel-containing film-forming material can contain the later-described compounds which become silicon sources, in addition to the nickel compound.

As a method to form a nickel-containing film in the invention, a CVD method is preferably utilized, but the method employable in the invention is not limited to the CVD method, and other method is employable provided that it is a film production method utilizing vapor of the nickel-containing film-forming material.

A general process for producing a metal silicide film is a process wherein a metal compound which becomes a metal source and a silane compound which becomes a silicon source are allowed to react with each other.

In the process for producing a nickel silicide film of the invention, it is essential to use the nickel compound as a nickel source. The silicon source is not specifically restricted, but for example, a compound represented by SiₙH₍₂ₙ₊₂₎ (n is an integer of 1 to 3) or RₙSiH₍₄₋ₙ₎ (n is an integer of 1 to 3, and R is an alkyl group of 1 to 3 carbon atoms) is preferable. As such a compound, silane, methylsilane, dimethylsilane, trimethylsilane, ethylsilane, diethylsilane, triethylsilane, disilane or trisilane is preferably used.

In the case of the nickel-containing film-forming material composed of a nickel compound having a group with a structure represented by the aforesaid formula (2), a nickel silicide film can be formed by utilizing silicon in the nickel compound as a silicon source. However, it is also possible to form a nickel silicide film by using another silicon source in combination. As the silicon source used in combination, a compound represented by SiₙH₍₂ₙ₊₂₎ (n is an integer of 1 to 3) or RₙSiH₍₄₋ₙ₎ (n is an integer of 1 to 3, and R is an alkyl group of 1 to 3 carbon atoms) is preferable. Examples of such compounds include silane, methylsilane, dimethylsilane, trimethylsilane, ethylsilane, diethylsilane, triethylsilane, disilane and trisilane.

For the production of a nickel silicide film, various CVD methods wherein a nickel source is decomposed can be utilized. That is to say, a thermal CVD method wherein the nickel source is thermally decomposed, a photo-CVD method wherein the nickel source is decomposed by heat and light, a plasma CVD method wherein the nickel source is activated with plasma and photo-decomposed, a laser assisted CVD method wherein the nickel source is activated with laser and photo-decomposed and an ion beam assisted CVD method wherein the nickel source is activated with ion beam and photo-decomposed can be mentioned as the CVD methods, and these methods can be utilized for producing a nickel silicide film.

In the production of a nickel silicide film, the reaction pressure is in the range of preferably 0.01 to 760 Torr, more preferably 0.1 to 760 Torr, still more preferably 1 to 760 Torr. The reaction temperature is in the range of preferably 50 to 800° C., more preferably 100 to 500° C.

### EXAMPLES

The present invention is further described with reference to the following examples, but it should be construed that the invention is in no way limited to those examples.

### Synthesis Example 1

In a 3000 ml flask purged with nitrogen, a tetrahydrofuran solution of cyclopentadienyl sodium (2.0 mol/liter, 800 ml) was dissolved in well-dried tetrahydrofuran (1 liter), and the solution was cooled to 0° C. To the solution, trimethylsilyl chloride (180 g) was dropwise added over a period of 1 hour in a stream of nitrogen, and then they were stirred at 0° C. for 2 hours. Thereafter, a salt was removed by filtration, and the filtrate was distilled to obtain trimethylsilylcyclopentadiene (70 g). The above operations were repeated to obtain 140 g of trimethylsilylcyclopentadiene.

In a 1000 ml flask purged with nitrogen, trimethylsilylcyclopentadiene (86 g) was dissolved in well-dried tetrahydrofuran (500 ml), and the solution was cooled to 0° C. To the solution, a hexane solution of n-butyllithium (2.6 mol/liter, 250 ml) was dropwise added over a period of 2 hours, and then they were heated to room temperature with stirring them for 1 hour to obtain a tetrahydrofuran solution of trimethylsilylcyclopentadienyl sodium.

Separately from the above, in a 2000 ml flask purged with nitrogen, 40 g of nickel (II) chloride was suspended in well-dried tetrahydrofuran (250 ml). To this solution, the tetrahydrofuran solution of trimethylsilylcyclopentadienyl sodium previously prepared was dropwise added over a period of 1 hour, and then they were refluxed for 1 hour. The resulting solution was cooled to room temperature over a period of 2 hours and stirred at room temperature for 10 hours, and thereafter, the solvent was removed by distillation. Then, well-dried hexane (150 ml) was added to precipitate a salt, thereafter the salt was removed by filtration in a nitrogen atmosphere, and the filtrate was distilled to obtain bis(trimethylsilylcyclopentadienyl)nickel (45.7 g, yield: 440%).

### Evaluation Example 1

The melting point of bis(trimethylsilylcyclopentadienyl)nickel obtained in Synthesis Example 1 was 15° C. Using an apparatus for simultaneous differential thermal analysis and thermogravimetry, an evaporation rate was measured, and from the Antoine equation, a vapor pressure was calculated. In the determination of a diffusion constant, the boiling point molar volume of nickel in the Gilliland equation was assumed to be 3 times the atomic volume. As a result, the temperature at which the vapor pressure became 1 Torr was 108° C. Further, the volatilization ratio given when the compound was heated up to 500° C. was 99.9%.

Measurements of a vapor pressure and a volatilization ratio of bis(methylcyclopentadienyl)nickel as a comparative compound were carried out in the same manner as those for bis(trimethylsilylcyclopentadienyl)nickel. As a result, the melting point of bis(methylcyclopentadienyl)nickel was not higher than 0° C., and the temperature thereof at which the vapor pressure became 1 Torr was 93° C. Further, the volatilization ratio given when this compound was heated up to 500° C. was 98.8%.

From the above results, bis(trimethylsilylcyclopentadienyl)nickel exhibited a lower vapor pressure than bis(methylcyclopentadienyl)nickel, but this compound had a volatilization ratio of 99.9% and was excellent in volatility though the molecular weight is high.

From this, bis(trimethylsilylcyclopentadienyl)nickel proved to be suitable as a film-forming material for forming a nickel-containing film by a CVD method.

### Example 1

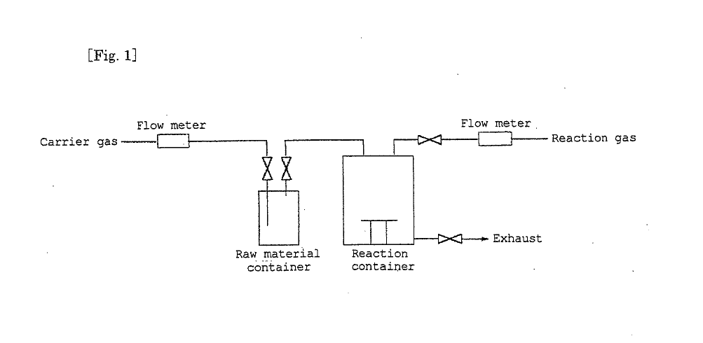

By the use of an apparatus shown in FIG. 1, formation of a nickel silicide film by a CVD method using bis(trimethylsilylcyclopentadienyl)nickel obtained in Synthesis Example 1 was carried out on a silicon substrate.

In a raw material container, bis(trimethylsilylcyclopentadienyl)nickel was placed, then the container was heated to 60° C., and as a carrier gas, a hydrogen gas was made to flow into a reaction container at a flow rate of 400 ml/min. The pressure in the system had been reduced to 10 to 20 Torr, and the substrate placed in the reaction container had been heated to 300° C.

Using an X-ray photoelectron spectrometer (XPS), composition of the film was examined, and as a result, presence of nickel and silicon was confirmed. Further, from the measurement using an X-ray diffraction apparatus, it was confirmed that this film was a nickel silicide film.

### Synthesis Example 2

In a 1000 ml flask purged with nitrogen, trimethylsilylcyclopentadiene (69 g) synthesized in Synthesis Example 1 and cyclopentadiene (33 g) were dissolved in well-dried tetrahydrofuran (500 ml), and the solution was cooled to 0° C. To the solution, a hexane solution of n-butyllithium (2.6 mol/liter, 380 ml) was dropwise added over a period of 1 hour, and then they were heated to room temperature with stirring them for 1 hour to obtain a tetrahydrofuran solution of trimethylsilylcyclopentadienyl sodium and cyclopentadienyl sodium.

Separately from the above, in a 2000 ml flask purged with nitrogen, 65 g of nickel (II) chloride was suspended in well-dried tetrahydrofuran (500 ml). To this solution, the tetrahydrofuran solution of trimethylsilylcyclopentadienyl sodium and cyclopentadienyl sodium previously prepared was dropwise added over a period of 1 hour, and then they were allowed to react with each other at 60° C. for 5 hours. The resulting solution was cooled to room temperature over a period of 2 hours and stirred at room temperature for 10 hours, and thereafter, the solvent was removed by distillation. Then, well-dried hexane (200 ml) was added to precipitate a salt, thereafter the salt was removed by filtration in a nitrogen atmosphere, and the filtrate was distilled, whereby (cyclopentadienyl)(trimethylsilylcyclopentadienyl)nickel was separated and obtained (48.0 g, yield: 18%).

### Evaluation Example 2

The melting point of (cyclopentadienyl)(trimethylsilylcyclopentadienyl)nickel obtained in Synthesis Example 2 was 25° C. Using an apparatus for simultaneous differential thermal analysis and thermogravimetry, an evaporation rate was measured, and from the Antoine equation, a vapor pressure was calculated. In the determination of a diffusion constant, the boiling point molar volume of nickel in the Gilliland equation was assumed to be 3 times the atomic volume. As a result, the temperature at which the vapor pressure became 1 Torr was 101° C. Further, the volatilization ratio given when the compound was heated up to 500° C. was 99.9%.

From the above results, (cyclopentadienyl)(trimethylsilylcyclopentadienyl)nickel exhibited a lower vapor pressure than bis(methylcyclopentadienyl)nickel, but this compound had a low melting point and a volatilization ratio of 99.9%, so that this compound is excellent in handling and volatility.

From this, (cyclopentadienyl)(trimethylsilylcyclopentadienyl)nickel proved to be suitable as a film-forming material for forming a nickel-containing film by a CVD method.

### Example 2

By the use of an apparatus shown in FIG. 1, formation of a nickel silicide film by a CVD method using (cyclopentadienyl)(trimethylsilylcyclopentadienyl)nickel obtained in Synthesis Example 2 was carried out on a silicon substrate.

In a raw material container, (cyclopentadienyl)(trimethylsilylcyclopentadienyl)nickel was placed, then the container was heated to 60° C., and as a carrier gas, a hydrogen gas was made to flow into a reaction container at a flow rate of 400 ml/min. The pressure in the system had been reduced to 10 to 20 Torr, and the substrate placed in the reaction container had been heated to 300° C.

Using an X-ray photoelectron spectrometer (XPS), composition of the film was examined, and as a result, it was confirmed that nickel was present in a proportion of 51% and silicon was present in a proportion of 38%. Further, as a result of analysis by an X-ray diffraction apparatus, peaks of NiSi and Ni₂Si were detected, and from this, it was confirmed that this film was a nickel silicide film.

1. A nickel-containing film-forming material comprising a compound represented by a structural formula of the following formula (1):
Ni(R¹ₐC₅H₍₅₋ₐ₎)(R²_{b}C₅H_{(5-b)} (1)
wherein C₅H₍₅₋ₐ₎ and C₅H_{(5-b)} are each a cyclopentadienyl ring, R¹ and R² are each independently a hydrogen atom or a group represented by a structural formula of the following formula (2), a and b are each an integer of 0 to 4, and a and b satisfy the condition of 0<a+b≦4 with the exception of a case where R¹ and R² are both hydrogen atoms, 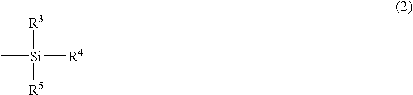
wherein R³, R⁴ and R⁵ are each independently an alkyl group of 1 to 2 carbon atoms.

2. The nickel-containing film-forming material as claimed in claim 1, wherein R³, R⁴ and R⁵ in the formula (2) are all methyl groups.

3. The nickel-containing film-forming material as claimed in claim 1, wherein the compound represented by a structural formula of the formula (1) is bis(trimethylsilylcyclopentadienyl)nickel or (cyclopentadienyl)(trimethylsilylcyclopentadienyl)nickel.

4. The nickel-containing film-forming material as claimed in claim 1, which is a material for forming a nickel-containing film using a CVD (chemical vapor deposition) method.

5. The nickel-containing film-forming material as claimed in claim 4, wherein the nickel-containing film is a nickel silicide film.

6. A nickel silicide film formed by the use of the nickel-containing film-forming material as claimed in claim 1.

7. A process for producing a nickel silicide film, comprising forming a nickel silicide film by a CVD (chemical vapor deposition) method using the nickel-containing film-forming material as claimed in claim 1.

8. The process for producing a nickel silicide film as claimed in claim 7, wherein as a silicon source of the nickel silicide film, silicon in the group represented by a structure of the formula (2) is utilized.

9. The process for producing a nickel silicide film as claimed in claim 7, wherein the nickel-containing film-forming material is bis(trimethylsilylcyclopentadienyl)nickel or (cyclopentadienyl)(trimethylsilylcyclopentadienyl)nickel.

10. The process for producing a nickel silicide film as claimed in claim 8, wherein the nickel-containing film-forming material is bis(trimethylsilylcyclopentadienyl)nickel or (cyclopentadienyl)(trimethylsilylcyclopentadienyl)nickel.
